(19) United States
(12) Patent Application Publication
(10) Pub. No.: US 2026/0150248 A1
(43) Pub. Date: May 28, 2026

(54) Information Handling System Thermal Transfer System

(71) Applicant: Dell Products L.P., Round Rock, TX (US)

(72) Inventors: Eduardo Escamilla, Round Rock, TX (US); Robert Proulx, Holden, MA (US); Obinna Uyanna, Austin, TX (US)

(21) Appl. No.: 18/961,653

(22) Filed: Nov. 27, 2024

(51) Int. Cl. H05K 7/20

(52) U.S. Cl. CPC H05K 7/20418; H05K 7/2049; H05K 7/20154

(57) ABSTRACT

A thermal transfer system for use with an information handling system. The thermal transfer system includes a fan component and a multi stage heat sink system. The multi stage heat sink system includes: a primary heat sink component, the primary heat sink component being thermally coupled to a heat producing component within the information handling system, the primary heat sink component providing a primary heat sink thermal transfer stage; a secondary heat sink component, the secondary heat sink component providing a secondary heat sink thermal transfer stage; and, a thermal coupling component, the secondary heat sink component being thermally coupled with the primary heat sink component via the thermal coupling component, the secondary heat sink component providing additional surface area for transferring thermal energy away from the heat producing component.

### BACKGROUND OF THE INVENTION

### FIELD OF THE INVENTION

The present invention relates to information handling systems. More specifically, embodiments of the invention relate to server type information handling systems within information technology (IT) environments.

### DESCRIPTION OF THE RELATED ART

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing an information handling system with a thermal transfer system.

In one embodiment, the invention relates to a multi stage heat sink system of a thermal transfer system for an information handling system, comprising: a primary heat sink component, the primary heat sink component being thermally coupled to a heat producing component within the information handling system, the primary heat sink component providing a primary heat sink thermal transfer stage; a secondary heat sink component, the secondary heat sink component providing a secondary heat sink thermal transfer stage; and, a thermal coupling component, the secondary heat sink component being thermally coupled with the primary heat sink component via the thermal coupling component, the secondary heat sink component providing additional surface area for transferring thermal energy away from the heat producing component.

In another embodiment, the invention relates to a thermal transfer system for use in an information handling system comprising: a fan component; and, a multi stage heat sink system, the multi stage heat sink system comprising: a primary heat sink component, the primary heat sink component being thermally coupled to a heat producing component within the information handling system, the primary heat sink component providing a primary heat sink thermal transfer stage; a secondary heat sink component, the secondary heat sink component providing a secondary heat sink thermal transfer stage; and, a thermal coupling component, the secondary heat sink component being thermally coupled with the primary heat sink component via the thermal coupling component, the secondary heat sink component providing additional surface area for transferring thermal energy away from the heat producing component.

In another embodiment, the invention relates to an information handling system comprising: a chassis; a heat producing component contained within the chassis; a fan component contained within the chassis; and, a multi stage heat sink system, the multi stage heat sink system comprising: a primary heat sink component, the primary heat sink component being thermally coupled to a heat producing component within the information handling system, the primary heat sink component providing a primary heat sink thermal transfer stage; a secondary heat sink component, the secondary heat sink component providing a secondary heat sink thermal transfer stage; and, a thermal coupling component, the secondary heat sink component being thermally coupled with the primary heat sink component via the thermal coupling component, the secondary heat sink component providing additional surface area for transferring thermal energy away from the heat producing component.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A, 4B and 4C, generally referred to as FIG. 4, show block diagrams of embodiments of a thermal transfer system.

FIG. 5 show a perspective view of thermal transfer systems mounted within an information handling system.

FIGS. 6A, 6B, 6C 6D, 6E, 6F, 6G, 6H, 6I, and 6J, generally referred to as FIG. 6, show a plurality of views of a multi stage heat sink system.

### DETAILED DESCRIPTION

Various aspects of the present disclosure include an appreciation that various components within information handling systems generate heat. Various aspects of the present disclosure include an appreciation that removing high heat from components which have a small surface area, such as processors or application specific integrated circuits (ASICs) can present a difficult technical challenge. Various aspects of the present disclosure include an appreciation that it is known to use heat sinks to increase heat transfer away from a component. Various aspects of the present disclosure include an appreciation that heat sinks are often configured with fins extending from a base which is thermally coupled with a surface of the heat source

Various aspects of the present disclosure include an appreciation that heat sinks are often used in combination with high thermally conductive heat-pipe components to move heat from the location within an information handling system where the heat is being generated to another location within the information handling system. Various aspects of the present disclosure include an appreciation that it is known to connect heat-pipe components to fins positioned away from the main source of the heat. Various aspects of the present disclosure include an appreciation that heat-pipe components often have relatively small cross sections. Various aspects of the present disclosure include an appreciation that connecting heat-pipe components to fins positioned away from the main source of the heat can be challenging.

Accordingly, various aspects of the present disclosure include an appreciation that it would be desirable to increase the thermal transfer capacity of heat sinks and heat-pipe combinations.

A system and method are disclosed for providing an information handling system with a thermal transfer system. In certain embodiments, the thermal transfer system includes a multi stage heat sink. In certain embodiments, a primary heat sink base is thermally coupled to a secondary heatsink base. In certain embodiments, the stages of the multi stage heat sink are thermally coupled via a heat-pipe component structure. In certain embodiments, the heat pipe component structure thermally couples a primary heat sink base to a secondary heatsink base.

In certain embodiments, the secondary heat sink includes a secondary heat sink base as well as a top fin structure extending from the secondary heat sink base. In certain embodiments, the secondary heat sink further includes a bottom fin structure extending from the secondary heat sink base.

Such a thermal transfer system advantageously allows larger heatsinks to be used in conventional cooling of components within an information handling system. Such a thermal transfer system advantageously provides more fin surface area to be engaged for cooling the heat producing component.

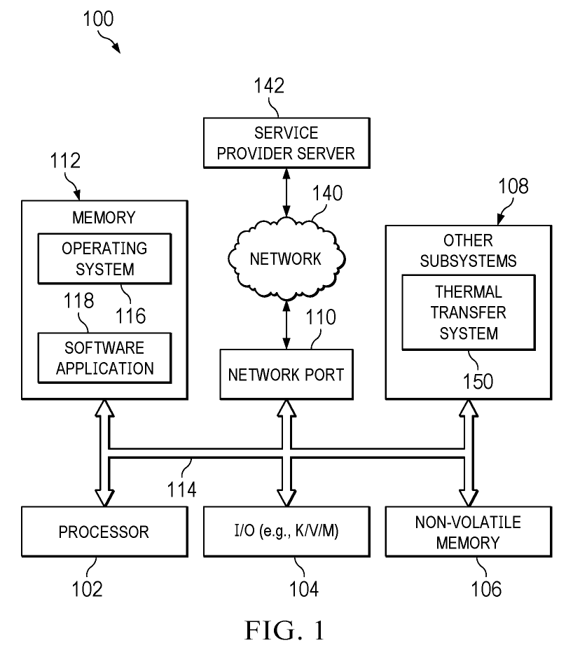

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a thermal transfer system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the thermal transfer system 150 includes a fan module and a heat sink. In certain embodiments, the heat sink includes a multi stage heat sink. In certain embodiments, a primary heat sink base is thermally coupled to a secondary heatsink base. In certain embodiments, the stages of the multi stage heat sink are thermally coupled via a heat-pipe component structure. In certain embodiments, the heat pipe component structure thermally couples a primary heat sink base to a secondary heatsink base.

In certain embodiments, the secondary heat sink includes a secondary heat sink base as well as a top fin structure extending from the secondary heat sink base. In certain embodiments, the secondary heat sink further includes a bottom fin structure extending from the secondary heat sink base.

Such a thermal transfer system advantageously allows larger heatsinks to be used in conventional cooling of components within an information handling system. Such a thermal transfer system advantageously providing additional surface area for transferring thermal energy away from the heat producing component. Such a thermal transfer system provides the additional surface area by providing enabling more fin surface area to be engaged for cooling the heat producing component.

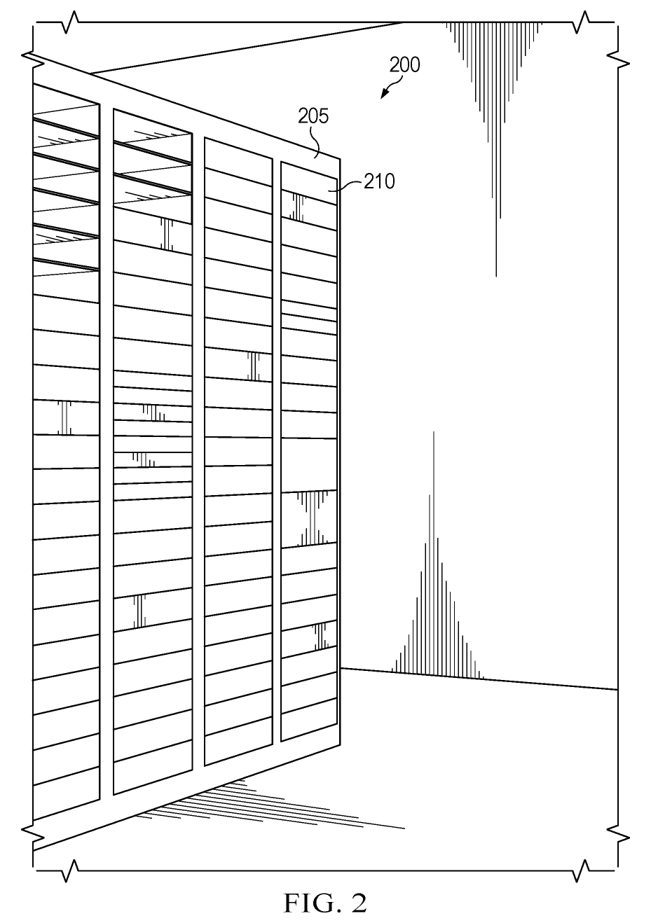

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/-20%) 1.75” high, a 2U rack unit is substantially (i.e., +/-20%) 3.5” high, and a 4U rack height is substantially (i.e., +/-20%) 7.0” high.

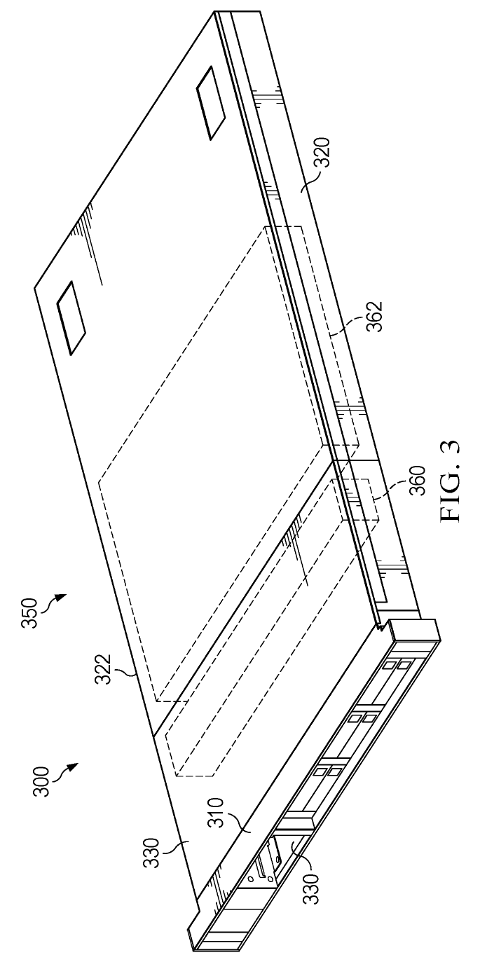

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300.

In certain embodiments, the blade type information handing system 300 includes a one or more device bays 350. In certain embodiments, the information handling system 300 includes a fan system 360, a heat sink system 362, or a combination thereof. In certain embodiments, the fan system 360 and the heat sink system 362 provide a heat transfer system.

In certain embodiments, the heat sink system 362 includes a multi stage heat sink. In certain embodiments, a primary heat sink base is thermally coupled to a secondary heatsink base. In certain embodiments, the stages of the multi stage heat sink are thermally coupled via a heat-pipe component structure. In certain embodiments, the heat pipe component structure thermally couples a primary heat sink base to a secondary heatsink base.

In certain embodiments, the secondary heat sink includes a secondary heat sink base as well as a top fin structure extending from the secondary heat sink base. In certain embodiments, the secondary heat sink further includes a bottom fin structure extending from the secondary heat sink base.

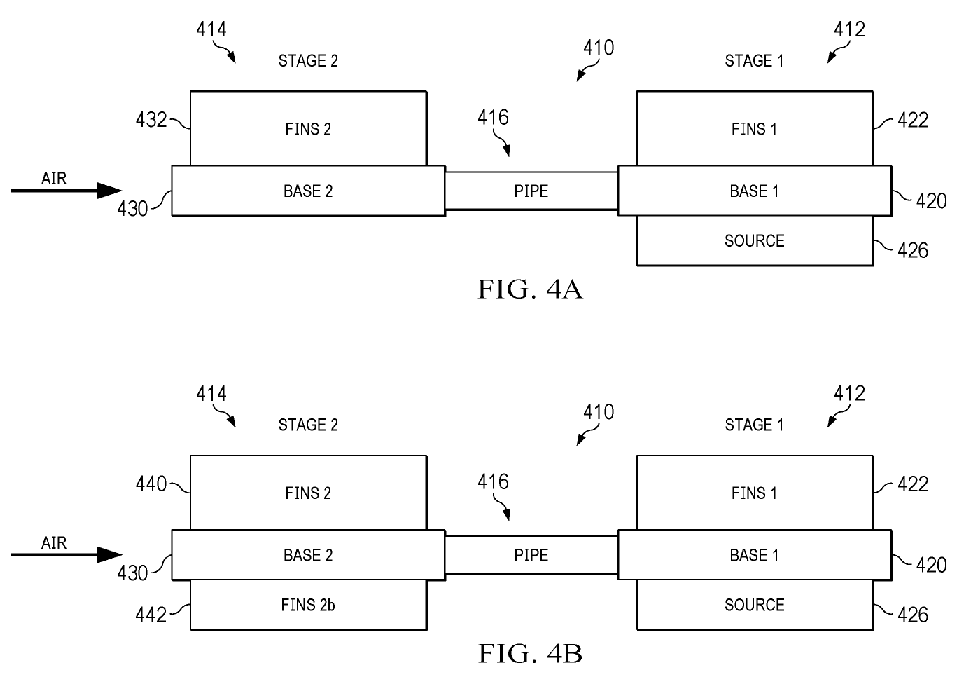

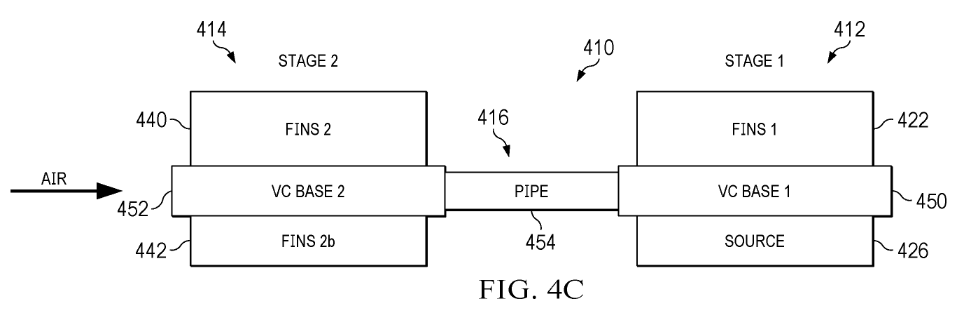

FIGS. 4A, 4B and 4C, generally referred to as FIG. 4, show block diagrams of embodiments of a heat sink system. More specifically, FIG. 4A shows a block diagram of an embodiment of a heat sink system. FIG. 4B shows a block diagram of another embodiment of a heat sink system. FIG. 4C shows a block diagram of another embodiment of a heat sink system.

Referring now to FIG. 4A, a heat sink system 410 includes a primary heat sink component 412, a secondary heat sink component 414, a thermal coupling component 416, or a combination thereof. In certain embodiments, the primary heat sink component 412 provides a primary heat sink thermal transfer stage (Stage 1). In certain embodiments, the secondary heat sink component 414 provides a secondary heat sink thermal transfer stage (Stage 2).

In certain embodiments, the primary heat sink component 412 includes a primary heat sink base 420, a primary heat sink fin structure 422, or a combination thereof. In certain embodiments, the primary heat sink fin structure 422 is physically and thermally coupled with the primary heat sink base 420. In certain embodiments, the primary heat sink base 420 is thermally coupled to a heat source 426. In certain embodiments, the secondary heat sink component 414 includes a secondary heat sink base 430, a secondary heat sink fin structure 432, or a combination thereof. In certain embodiments, the secondary heat sink fin structure 632 is physically and thermally coupled with the secondary heat sink base 430.

In certain embodiments, the secondary heat sink component 414 is thermally coupled to the primary heat sink component 412. In certain embodiments, the secondary heat sink base 430 is thermally coupled to the primary heat sink base 420. In certain embodiments, the secondary component 412 is thermally coupled to the primary heat sink component 410 via the thermal coupling component 414. In certain embodiments, the secondary heat sink base 430 is thermally coupled to the primary heat sink base 420 via the thermal coupling component 414. In certain embodiments, the thermal coupling component 414 includes a heat pipe structure. In certain embodiments, the heat pipe structure includes a plurality of heat pipes. In certain embodiments, each of the plurality of heat pipes comprises an elongated cylindrical device which is configured as a sealed chamber containing volatile liquid which transfers heat by conduction, phase transition, or a combination thereof.

Referring now to FIG. 4B, a heat sink system 410 includes a primary heat sink component 412, a secondary heat sink component 414, a thermal coupling component 416, or a combination thereof. In certain embodiments, the primary heat sink component 412 provides a primary heat sink stage (Stage 1). In certain embodiments, the secondary heat sink component 414 provides a secondary heat sink stage (Stage 2).

In certain embodiments, the primary heat sink component 412 includes a primary heat sink base 420, a primary heat sink fin structure 422, or a combination thereof. In certain embodiments, the primary heat sink fin structure 422 is physically and thermally coupled with the primary heat sink base 420. In certain embodiments, the primary heat sink base 420 is thermally coupled to a heat source 426. In certain embodiments, the secondary heat sink component 414 includes a secondary heat sink base 430, a first secondary heat sink fin structure 440, a second secondary heat sink fin structure 442, or a combination thereof. In certain embodiments, the first secondary heat sink fin structure 640 is physically and thermally coupled with a top surface of the secondary heat sink base 430. In certain embodiments, the second secondary heat sink fin structure 640 is physically and thermally coupled with a bottom surface of the secondary heat sink base 430.

In certain embodiments, the secondary heat sink component 414 is thermally coupled to the primary heat sink component 412. In certain embodiments, the secondary heat sink base 430 is thermally coupled to the primary heat sink base 420. In certain embodiments, the secondary component 412 is thermally coupled to the primary heat sink component 410 via the thermal coupling component 414. In certain embodiments, the secondary heat sink base 430 is thermally coupled to the primary heat sink base 420 via the thermal coupling component 414. In certain embodiments, the thermal coupling component 414 includes a heat pipe structure. In certain embodiments, the heat pipe structure includes a plurality of heat pipes. In certain embodiments, each of the plurality of heat pipes comprises an elongated cylindrical device which is configured as a sealed chamber containing volatile liquid which transfers heat by conduction, phase transition, or a combination thereof.

Referring now to FIG. 4C, a heat sink system 410 may be configured to use vapor chambers as a primary heat sink base vapor chamber 450 and a secondary heat sink base vapor chamber 452. In this embodiment, a heat pipe structure 454 thermally couples the primary heat sink base vapor chamber 450 and the secondary heat sink base vapor chamber 452. In certain embodiments, the heat pipe structure 454 functions as a vapor chamber connection to effectively provide a single continuous vapor chamber. Providing a single continuous vapor chamber further improves the heat transfer from the primary stage (Stage1) to the secondary stage (Stage 2).

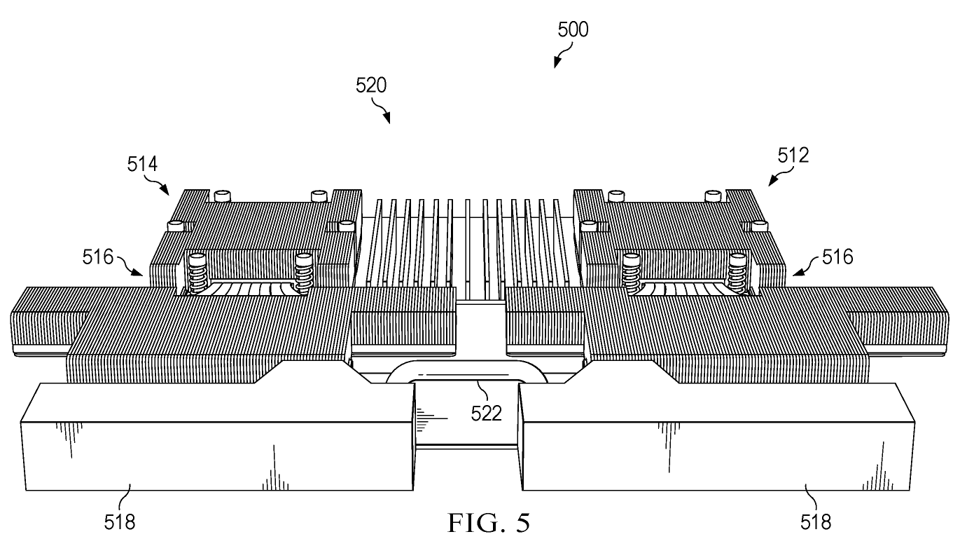

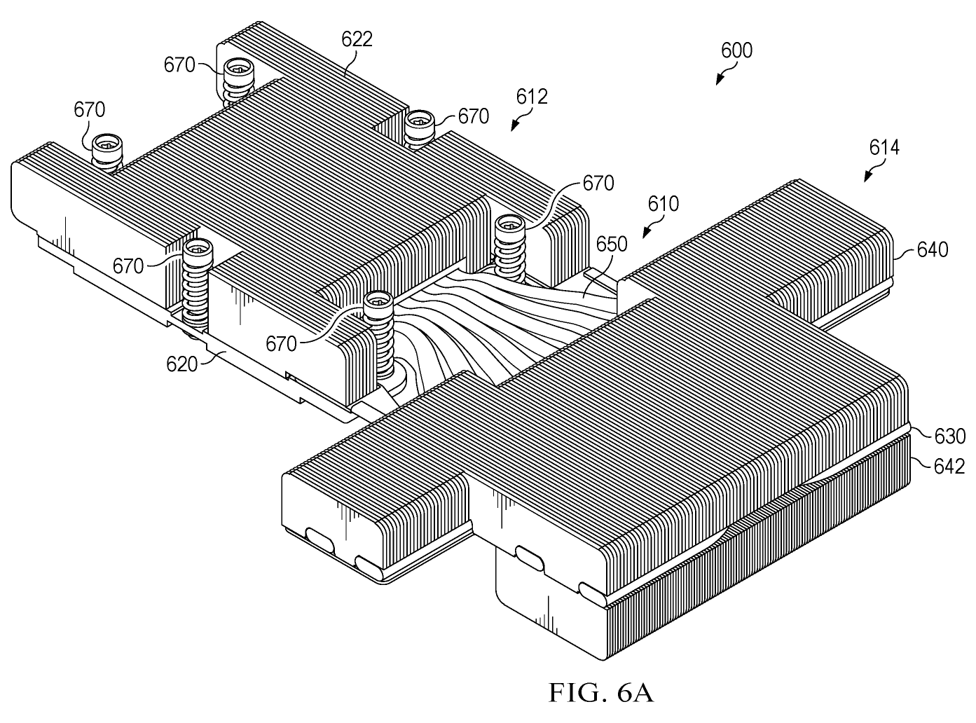

FIG. 5 shows a perspective view of thermal transfer systems mounted within an information handling system 500. More specially, in certain embodiments, the information handling system 500 includes a first thermal transfer system 512, a second thermal transfer system 514, or a combination thereof. In certain embodiments, each thermal transfer system 512, 514 corresponds to a thermal transfer system 150.

In certain embodiments, each thermal transfer system 512, 514 includes a respective multi stage heat sink system 516, a respective fan component 518, or a combination thereof. In certain embodiments, the fan component 518 is positioned to provide air flow across its respective multi stage heat sink system 516. In certain embodiments, the fan component 518 is positioned to provide air flow across a second stage of a respective multi stage heat sink system 516 and then a first stage of the respective multi stage heat sink system.

In certain embodiments, each multi stage heat sink system 516 is configured to be thermally coupled with a respective heat source. In certain embodiments, each respective heat source corresponds to a high heat component of the information handling system. In certain embodiments, each high heat component has a relatively a small surface area to which the heat sink system may be thermally coupled. In certain embodiments, each high heat component includes a processor system such as a system on a chip (SoC) type processor system, a graphics processing unit (GPU) module, an application specific integrated circuit (ASIC), or a combination thereof.

In certain embodiments, the information handling system 500 also includes additional components 520 mounted between the first thermal transfer system 512 and the second thermal transfer system 514. In certain embodiments, the additional components 520 are mounted in parallel between the first thermal transfer system 512 and the second thermal transfer system 514. In certain embodiments, the additional components 520 include a plurality of memory modules. In certain embodiments, first stages of the thermal transfer systems 512, 514 are sized such that the additional components 520 can be mounted between the first thermal transfer system 512 and the second thermal transfer system 514.

In certain embodiments, the information handling system 500 also includes a handle 522 mounted between the first thermal transfer system 512 and the second thermal transfer system 514. In certain embodiments, the handle 522 facilitates installation and removal of the portion of the information handling system 500 to which the first thermal transfer system 512 and the second thermal transfer system 514 are attached. In certain embodiments, second stages of the thermal transfer systems 512, 514 are sized such that the handle 522 can be mounted between the first thermal transfer system 512 and the second thermal transfer system 514.

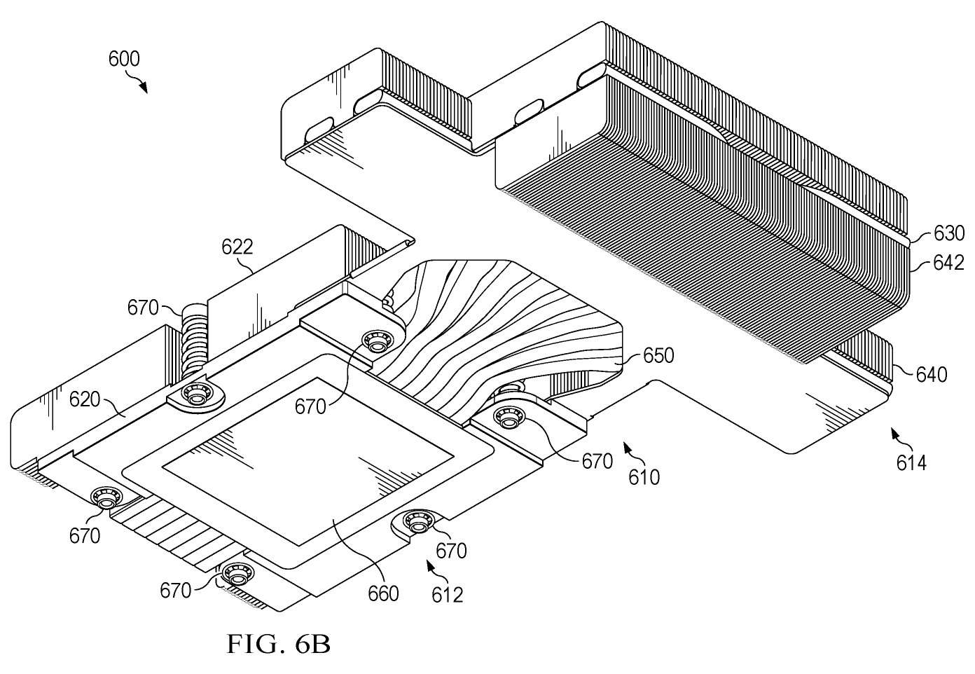

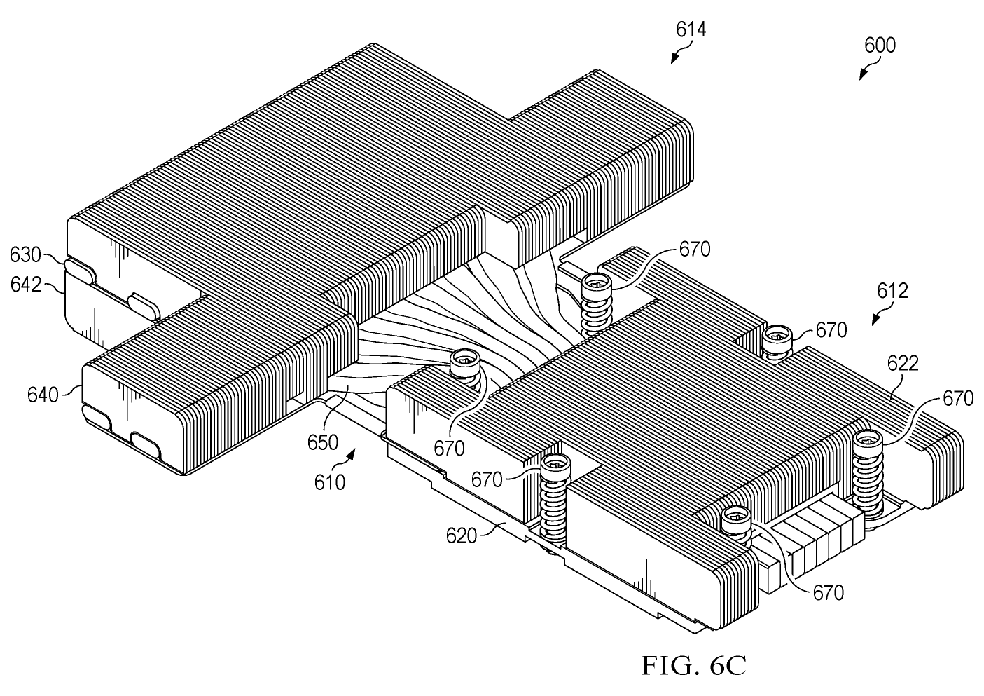

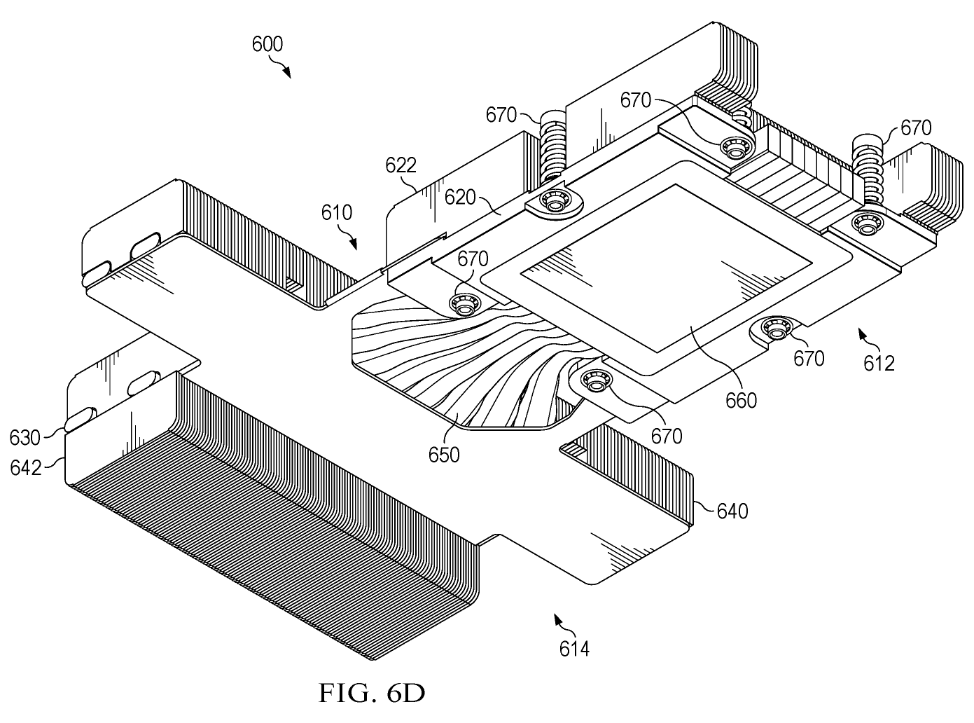

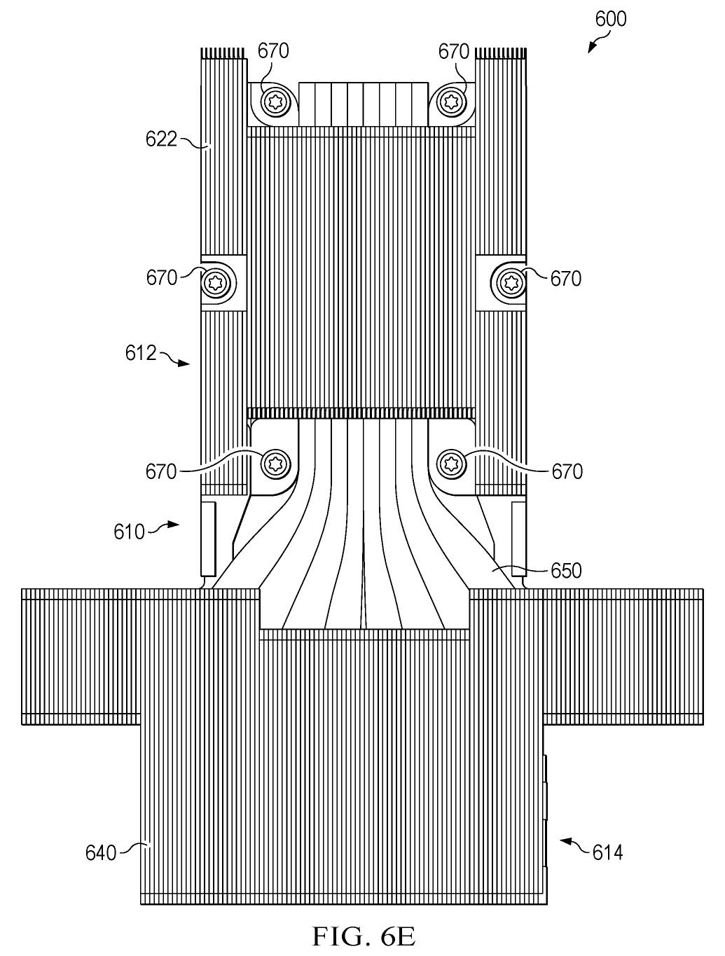

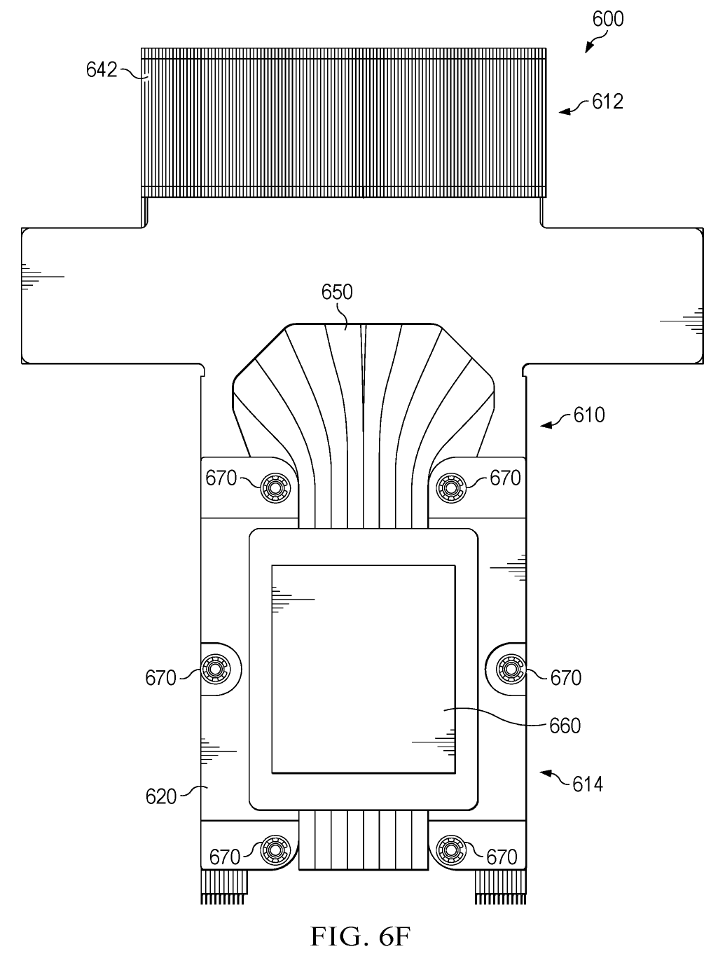

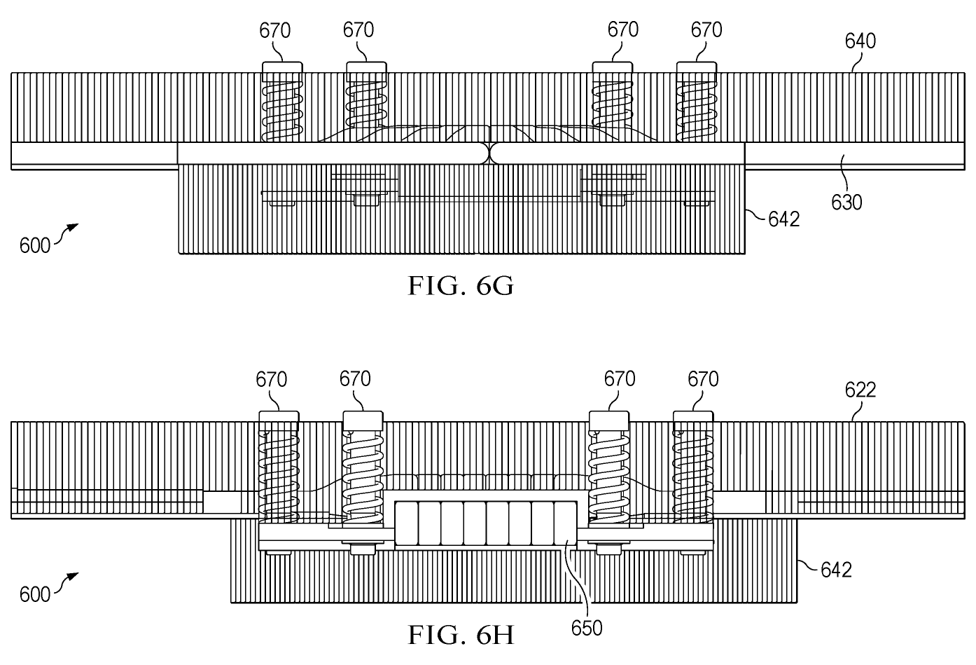

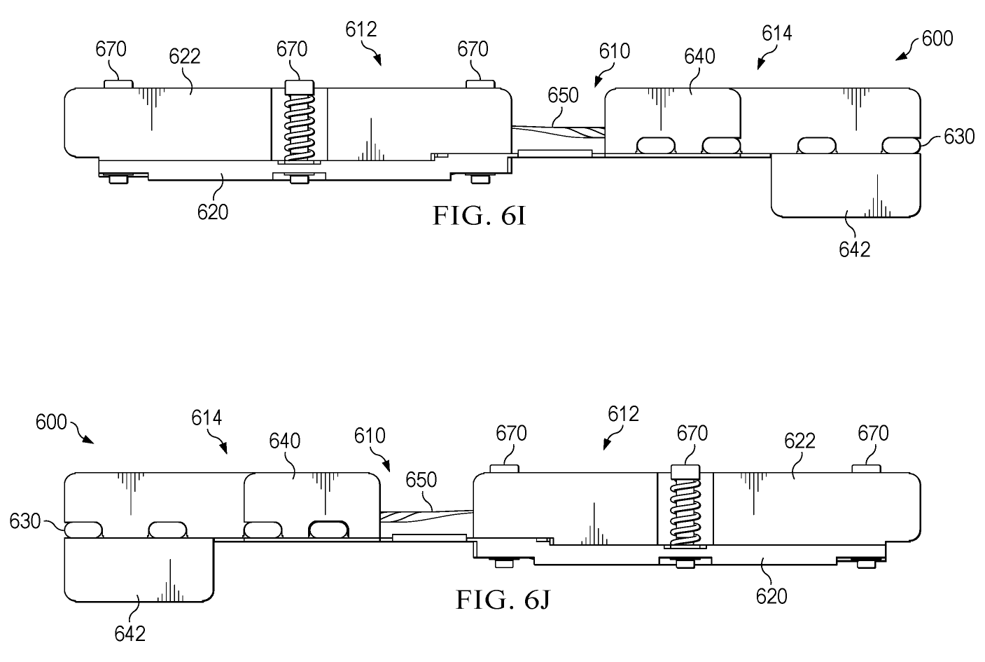

FIGS. 6A, 6B, 6C 6D, 6E, 6F, 6G, 6H, 6I, and 6H, generally referred to as FIG. 6, show a plurality of views of a multi stage heat sink system 600. More specifically, FIG. 6A shows a front top perspective view of a multi stage heat sink system 600. FIG. 6B shows a front bottom perspective view of a multi stage heat sink system 600. FIG. 6C shows a rear top perspective view of a multi stage heat sink system 600. FIG. 6D shows a rear bottom perspective view of a multi stage heat sink system 600. FIG. 6E shows a top view of a multi stage heat sink system 600. FIG. 6F shows a bottom view of a multi stage heat sink system 600. FIG. 6G shows a rear view of a multi stage heat sink system 600. FIG. 6H shows a left view of a multi stage heat sink system 600. FIG. 6I shows a right view of a multi stage heat sink system 600. FIG. 6J shows a left view of a multi stage heat sink system 600. In certain embodiments, the multi stage heat sink system 600 corresponds to a heat sink of the thermal transfer system 150.

In certain embodiments, the heat sink system 600 includes a primary heat sink component 612, a secondary heat sink component 614, a thermal coupling component 616, or a combination thereof. In certain embodiments, the primary heat sink component 612 provides a primary heat sink stage (Stage 1). In certain embodiments, the secondary heat sink component 614 provides a secondary heat sink stage (Stage 2). In certain embodiments, the primary heat sink component 612 has a corresponding primary heat distribution surface area. In certain embodiments, the secondary heat sink component 614 has a corresponding secondary heat distribution surface area. In certain embodiments, the secondary heat distribution surface area is greater than the primary heat distribution surface area.

In certain embodiments, the primary heat sink component 612 includes a primary heat sink base 620, a primary heat sink fin structure 622, or a combination thereof. In certain embodiments, the primary heat sink fin structure 622 is physically and thermally coupled with the primary heat sink base 620. In certain embodiments, the primary heat sink base 620 is thermally coupled to a heat source. In certain embodiments, the secondary heat sink component 614 includes a secondary heat sink base 630, a first secondary heat sink fin structure 640, a second secondary heat sink fin structure 642, or a combination thereof. In certain embodiments, the first secondary heat sink fin structure 640 is physically and thermally coupled with a top surface of the secondary heat sink base 630. In certain embodiments, the second secondary heat sink fin structure 640 is physically and thermally coupled with a bottom surface of the secondary heat sink base 630.

In certain embodiments, the secondary heat sink base 630 is wider, at least in places, than the primary heat sink base 620. In certain embodiments, the first secondary heat sink fin structure 640 is wider, at least in places, than the primary heat sink fin structure 622. In certain embodiments, the additional width of the first secondary heat sink fin structure 640 contributes to the secondary heat distribution surface area being greater than the primary heat distribution area. In certain embodiments, the second secondary heat sink fin structure 642 contributes to the secondary heat distribution surface area being greater than the primary heat distribution surface area.

In certain embodiments, the secondary heat sink component 614 is thermally coupled to the primary heat sink component 612. In certain embodiments, the secondary heat sink base 630 is thermally coupled to the primary heat sink base 620. In certain embodiments, the secondary component 612 is thermally coupled to the primary heat sink component 600 via the thermal coupling component 614. In certain embodiments, the secondary heat sink base 630 is thermally coupled to the primary heat sink base 620 via the thermal coupling component 614. In certain embodiments, the thermal coupling component 614 includes a heat pipe structure.

In certain embodiments, the heat pipe structure includes a plurality of heat pipes 650. In certain embodiments, each of the plurality of heat pipes 650 comprises an elongated cylindrical device which is configured as a sealed chamber containing volatile liquid which transfers heat by conduction, phase transition, or a combination thereof. In certain embodiments, the thermal coupling component 614 is configured with a first width to interact with the primary heat sink base 620. In certain embodiments, the thermal coupling component 614 is configured with a second width to interact with the secondary heat sink base 622. In certain embodiments, the second width is wider than the first width. In certain embodiments, by so configuring the widths of the thermal coupling component 614 heat is distributed from a narrower first stage multi stage heat sink system 600 to a wider second stage of the multi stage heat sink system 600.

In certain embodiments, at least some of the plurality of heat pipes are arched to transition between the first width and the second width (see e.g., FIGS. 6E and 6F). In certain embodiments, at least some of the plurality of heat pipes are leftwardly arched to transition between the first width and the second width. In certain embodiments, at least some of the plurality of heat pipes are rightwardly arched to transition between the first width and the second width. In certain embodiments, the plurality of heat pipes are progressively more severely arched to transition between the first width and the second width. In certain embodiments, the heat pipes are progressively more severely arched to transition from a center position to an edge portion of the heat pipes.

In certain embodiments, the multi stage heat sink system 600 includes one or more fastener components 670. In certain embodiments, the one or more fastener components 670 thermally attach, physically attach, or a combination thereof, the multi stage heat sink system 600 within an information handling system. In certain embodiments, the one or more fastener components 670 includes respective springs to control a torque via which the multi stage heat sink system 600 is attached within the information handling system.

In certain embodiments, the multi stage heat sink system 600 is configured to be thermally coupled with a heat source. In certain embodiments, the primary heat sink component 612 of the multi stage heat sink system 600 includes a heat source mounting surface 660. In certain embodiments, the heat source mounting surface 660 is configured to thermally couple the multi stage heat sink system 600 with the heat source. In certain embodiments, the heat source corresponds to a high heat component of the information handling system. In certain embodiments, the high heat component has a relatively a small surface area to which the heat sink system may be thermally coupled. In certain embodiments, the high heat component includes a processor system such as a system on a chip (SoC) type processor system, a graphics processing unit (GPU) module, an application specific integrated circuit (ASIC), or a combination thereof.

In certain embodiments, the primary heat sink component 612 of the thermal transfer system 600 is sized such that additional components can be mounted next to the primary heat sink component 612 of the multi stage heat sink system 600. In certain embodiments, the primary heat sink component 612 of the thermal transfer system 600 is sized such that additional components can be the thermal transfer system 600 and another thermal transfer system.

In certain embodiments, the secondary heat sink component 614 of the thermal transfer system 600 is sized such that a handle can be mounted next to the secondary heat sink component 614 of the multi stage heat sink system 600. In certain embodiments, the secondary heat sink component 614 of the thermal transfer system 600 is sized such that the handle can be the thermal transfer system 600 and another thermal transfer system.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A multi stage heat sink system of a thermal transfer system for an information handling system, comprising:
a primary heat sink component, the primary heat sink component being thermally coupled to a heat producing component within the information handling system, the primary heat sink component providing a primary heat sink thermal transfer stage;
a secondary heat sink component, the secondary heat sink component providing a secondary heat sink thermal transfer stage; and,
a thermal coupling component, the secondary heat sink component being thermally coupled with the primary heat sink component via the thermal coupling component, the secondary heat sink component providing additional surface area for transferring thermal energy away from the heat producing component.

2. The multi stage heat sink system of claim 1, wherein:
the primary heat sink component includes a primary heat sink base and a primary heat sink fin structure, the primary heat sink fin structure being physically and thermally coupled with the primary heat sink base.

3. The multi stage heat sink system of claim 2, wherein:
the secondary heat sink component includes a secondary heat sink base and a secondary heat sink fin structure, the secondary heat sink fin structure being physically and thermally coupled with the secondary heat sink base.

4. The multi stage heat sink system of claim 3, wherein:
the secondary heat sink fin structure includes a first secondary heat sink fin structure and a second secondary heat sink fin structure, the first secondary heat sink fin structure being physically and thermally coupled with a top surface of the secondary heat sink base, the second secondary heat sink fin structure being physically and thermally coupled with a bottom surface of the secondary heat sink base.

5. The multi stage heat sink system of claim 1, wherein:
the thermal coupling component comprises a heat pipe structure, the heat pipe structure being thermally coupled between the primary heat sink component and the secondary heat sink component.

6. The multi stage heat sink system of claim 5, wherein:
the heat pipe structure includes a plurality of heat pipes thermally coupled between the primary heat sink component and the secondary heat sink component.

7. A thermal transfer system for use in an information handling system comprising:
a fan component; and,
a multi stage heat sink system, the multi stage heat sink system comprising:
a primary heat sink component, the primary heat sink component being thermally coupled to a heat producing component within the information handling system, the primary heat sink component providing a primary heat sink thermal transfer stage;
a secondary heat sink component, the secondary heat sink component providing a secondary heat sink thermal transfer stage; and,
a thermal coupling component, the secondary heat sink component being thermally coupled with the primary heat sink component via the thermal coupling component, the secondary heat sink component providing additional surface area for transferring thermal energy away from the heat producing component.

8. The thermal transfer system of claim 7, wherein:
the primary heat sink component includes a primary heat sink base and a primary heat sink fin structure, the primary heat sink fin structure being physically and thermally coupled with the primary heat sink base.

9. The thermal transfer system of claim 8, wherein:
the secondary heat sink component includes a secondary heat sink base and a secondary heat sink fin structure, the secondary heat sink fin structure being physically and thermally coupled with the secondary heat sink base.

10. The thermal transfer system of claim 9, wherein:
the secondary heat sink fin structure includes a first secondary heat sink fin structure and a second secondary heat sink fin structure, the first secondary heat sink fin structure being physically and thermally coupled with a top surface of the secondary heat sink base, the second secondary heat sink fin structure being physically and thermally coupled with a bottom surface of the secondary heat sink base.

11. The thermal transfer system of claim 7, wherein:
the thermal coupling component comprises a heat pipe structure, the heat pipe structure being thermally coupled between the primary heat sink component and the secondary heat sink component.

12. The thermal transfer system of claim 11, wherein:
the heat pipe structure includes a plurality of heat pipes thermally coupled between the primary heat sink component and the secondary heat sink component.

13. An information handling system comprising:
a chassis;
a heat producing component contained within the chassis;
a fan component contained within the chassis; and,
a multi stage heat sink system contained within the chassis, the multi stage heat sink system comprising:
a primary heat sink component, the primary heat sink component being thermally coupled to the heat producing component within the information handling system, the primary heat sink component providing a primary heat sink thermal transfer stage;
a secondary heat sink component, the secondary heat sink component providing a secondary heat sink thermal transfer stage; and,
a thermal coupling component, the secondary heat sink component being thermally coupled with the primary heat sink component via the thermal coupling component, the secondary heat sink component providing additional surface area for transferring thermal energy away from the heat producing component.

14. The information handling system of claim 13, wherein:
the primary heat sink component includes a primary heat sink base and a primary heat sink fin structure, the primary heat sink fin structure being physically and thermally coupled with the primary heat sink base.

15. The information handling system of claim 14, wherein:
the secondary heat sink component includes a secondary heat sink base and a secondary heat sink fin structure, the secondary heat sink fin structure being physically and thermally coupled with the secondary heat sink base.

16. The information handling system of claim 15, wherein:
the secondary heat sink fin structure includes a first secondary heat sink fin structure and a second secondary heat sink fin structure, the first secondary heat sink fin structure being physically and thermally coupled with a top surface of the secondary heat sink base, the second secondary heat sink fin structure being physically and thermally coupled with a bottom surface of the secondary heat sink base.

17. The information handling system of claim 13, wherein:
the thermal coupling component comprises a heat pipe structure, the heat pipe structure being thermally coupled between the primary heat sink component and the secondary heat sink component.

18. The information handling system of claim 17, wherein:
the heat pipe structure includes a plurality of heat pipes thermally coupled between the primary heat sink component and the secondary heat sink component.
